(19) United States
(12) Patent Application Publication
(10) Pub. No.: US 2014/0020736 A1
(43) Pub. Date: Jan. 23, 2014

(54) METHOD FOR PRODUCING CIS-BASED THIN FILM, CIS-BASED THIN FILM PRODUCED BY THE METHOD AND THIN-FILM SOLAR CELL INCLUDING THE THIN FILM

(71) Applicant: KOREA INSTITUTE OF SCIENCE AND TECHNOLOGY, Seoul (KR)

(72) Inventors: Doh-Kwon LEE, Seoul (KR); Hong Gon KIM, Seoul (KR); Min Jae KO, Chungcheongnam-do (KR); Jin Young KIM, Gyeonggi-do (KR); Da Woon JEONG, Seoul (KR); Bong Soo KIM, Seoul (KR)

(73) Assignee: KOREA INSTITUTE OF SCIENCE AND TECHNOLOGY, Seoul (KR)

(21) Appl. No.: 13/670,784

(22) Filed: Nov. 7, 2012

(30) Foreign Application Priority Data
Jul. 17, 2012 (KR) 10-2012-0077794

(51) Int. Cl. H01L 31/18; H01L 31/04

(52) U.S. Cl. CPC H01L 31/18; H01L 31/04
USPC 136/252; 438/95; 257/431

(57) ABSTRACT

Disclosed is a method for producing a CIS-based thin film based on self-accelerated photoelectrochemical deposition. The method includes 1) mixing precursors of elements constituting a CIS-based compound with a solvent to prepare an electrolyte solution, 2) connecting an electrochemical cell including a working electrode, the electrolyte solution and a counter electrode to a voltage or current applying device to construct an electro-deposition circuit, 3) irradiating light onto the working electrode while at the same time applying a cathodic voltage or current to the working electrode to induce self-accelerated photoelectrochemical deposition, thereby electro-depositing a CIS-based thin film, and 4) annealing the electro-deposited CIS-based thin film under a gas atmosphere including sulfur or selenium.

### CROSS-REFERENCE TO RELATED APPLICATIONS

This application claims priority under 35 U.S.C. §119 to Korean Patent Application No. 10-2012-0077794 filed on Jul. 17, 2012, in the Korean Intellectual Property Office, the disclosure of which is incorporated herein by reference in its entirety.

### BACKGROUND OF THE INVENTION

1. Field of the Invention

The present invention relates to a method for producing a CIS-based thin film based on self-accelerated photoelectrochemical deposition, a CIS-based thin film produced by the method, and a thin-film solar cell including the thin film.

2. Description of the Related Art

Crystalline silicon solar cells account for most of the solar cells that are currently available in the market. However, unstable supply and demand of raw materials, high initial equipment investment costs and high maintenance costs are pointed out as problems of crystalline silicon solar cells. These problems limit the fabrication of crystalline silicon solar cells in an economical manner. Under such circumstances, there has been steadily growing interest and investment in thin-film solar cells that are used in a wide variety of applications because they can use relatively small amounts of raw materials and can be reduced in weight. Due to these advantages, the portion of thin-film solar cells in the overall market of solar cells is increasing year after year.

The photovoltaic efficiencies of copper indium gallium selenide (Cu(In₁₋ₓGaₓ)Se₂, CIGS) thin-film solar cells are at least 20%, which is at a level higher than those of other kinds of thin-film solar cells. The efficiency of CIS (for x=0) and CIGS thin-film solar cells is expected to reach the level of polycrystalline silicon solar cells. Thus, thin-film solar cells have received a great deal of attention as potential replacements for crystalline silicon solar cells. As one approach to fabricate CIGS solar cells at low cost, an attempt is being actively made to replace expensive indium (In) and gallium (Ga) with low-priced abundant elements, for example, zinc (Zn) and tin (Sn). In this case, photoactive layers are represented by Cu₂ZnSnS₄ (CZTS). It is also known that replacement of some or all of the selenium (Se) atoms in CIGS solar cells with sulfur (S) atoms can contribute to an increase in photovoltaic efficiency.

CIS, CIGS and CZTS (hereinafter, collectively referred to as “CIS-based”) light-absorbing layers can be produced by the following three methods: i) a coevaporation method in which constituent elements of a desired compound are deposited on a substrate by evaporation and simultaneously the formation reaction of the desired compound is induced; ii) a sputtering-selenization method in which constituent metal elements of a desired compound are deposited on a substrate by sputtering, followed by additional annealing to create the desired chalcogenide compound; and iii) a method in which a coating layer is formed by non-vacuum processing and is then annealed to form a dense thin film. Although the methods i) and ii) are advantageous for the formation of high-efficiency thin films, they require the installation and maintenance of expensive vacuum equipment and cause waste of raw materials whose efficiency of use is low. Accordingly, there is a limitation in saving the raw materials. The limited area of equipment and the limited uniformity of thin films lead to a difficulty in the manufacture of large-area modules.

For these reasons, techniques for the production of CIS-based thin films based on non-vacuum processing have been spotlighted recently because of the possibility of cost reduction through the economical processing, high efficiency of use of raw materials, and ease of large-area production. Such techniques are broadly classified into two methods. According to the first method, starting materials are completely dissolved in a solvent to prepare solution precursors or nanoparticles are dispersed in a solvent to prepare colloidal precursors, the precursors are processed into an ink or paste, and the ink or paste is coated on a substrate by spin coating, printing, spraying or electro-spinning. The second method is electro-deposition or electrochemical deposition in which an electric field is applied to solution precursors in the form of ions of components constituting a compound to coat the solution precursors on a substrate.

The CIS-based absorbing layer coated by non-vacuum processing commonly undergoes incomplete phase formation in many cases and is in the form of a porous thin film consisting of particles whose size is from several to several hundreds of nanometers. Accordingly, annealing is required for phase formation or densification of the coating layer, as in the sputtering-selenization method. A low packing density of the precursor coating layer makes it difficult to produce the absorbing thin-film layer with high quality for a high-efficiency solar cell. Better characteristics of the microstructure of the CIS-based thin film produced by the two-step process are ensured at a higher packing density of the precursor coating layer, leading to high efficiency of a solar cell. Generally, the packing density of the precursor coating layer increases in the order of sputtering, electro-deposition, solution precursor coating and colloidal precursor coating. This order is closely related to the order of the maximum efficiencies of solar cells fabricated by the respective precursor coating layer formation methods.

A low packing density of the precursor coating layer may cause the following problems. First, the grain growth is inhibited during annealing, impeding sufficient densification of the thin film. As a result, many pores are left in the light-absorbing layer and become causes of electron-hole recombination and leakage current under working conditions of a solar cell. Second, in a reaction furnace in an atmosphere including selenium or sulfur during annealing, the gas may pass through the coating layer and may react with molybdenum present in a substrate to form a thick molybdenum selenide layer. This increases the series resistance of a solar cell and hence the efficiency of the solar cell is deteriorated. Third, the surface roughness of the precursor coating layer having a low packing density tends to increase greatly in the course of annealing. The uneven and non-uniform surface of the light-absorbing layer causes deterioration of p-n junction characteristics.

Accordingly, annealing is required for phase formation or densification of the CIS-based coating layer and is typically conducted at 300° C. to 700° C. Lower temperature annealing is more advantageous for the reduction of processing cost and is essential for the fabrication of a high-efficiency tandem solar cell including two CIS-based solar cells having different band gaps and connected to each other in series. Generally, a higher packing density of the precursor coating layer contributes to the reduction of annealing temperature for phase formation/densificiation.

In view of this, methods for coating compound thin films based on non-vacuum processing are compared. A solution or colloidal coating method is advantageous in that the mixing ratio of starting materials is transferred unchanged to the composition of a compound thin film, making it easy to control the composition of the thin film, but has the disadvantage that the relatively lower packing density of a precursor coating layer makes it difficult to remove pores remaining after annealing. Another disadvantage of the solution or colloidal coating method is that an organic binder added to obtain a proper viscosity for the coating method and to improve the packing density of the coating layer causes a large amount of carbon residue left on the thin film after annealing of the precursor coating layer. In comparison with the solution or colloidal coating method, an electro-deposition method is advantageous in that a dense precursor coating layer can be obtained but has the disadvantages that it takes a long time for electro-deposition and it is difficult to control the composition of a compound thin film.

The rate of film formation in the electro-deposition method is limited by the reaction rate of an electrochemical cell for electro-deposition. Copper, indium and selenium cations in an electrolyte solution have to be diffused into the CIS/electrolyte interface during CIS electro-deposition. Since copper ions are more rapidly diffused than the other ions under general conditions, it is difficult to control the desired CuInSe₂ composition. Thus, there is a need to lower the diffusion rate of copper ions. For this purpose, an additive for the formation of a copper complex is also added to the electrolyte solution. It is, however, known that a copper (Cu)-deficient composition suitable for outstanding p-type semiconductor characteristics and high photovoltaic efficiency is difficult to achieve by electro-deposition. For this reason, methods are proposed wherein an In₂Se₃ layer is formed on the CIS light-absorbing layer by electro-deposition to form a bilayer structure or indium (In) is additionally supplied by physical vapor deposition (PVD). However, these methods may cause complexity of the processing and low reproducibility of thin film characteristics.

When a semiconducting material is irradiated by light, electron-hole pairs are created by exciting an electron from the valence band of the semiconductor to the conduction band. Based on this principle, Korean Unexamined Patent Publication No. 2010-89898 discloses a method for electrochemically depositing a conductive metal electrode of a solar cell. Specifically, this method ensures uniformity of metal materials deposited to produce an electrode of a solar cell. To this end, the method includes bringing the surface of a cathode of a solar cell into contact with an electrolyte solution, connecting the surface of an anode of the solar cell exposed to air to a solid metal plate immersed in the electrolyte solution via a wire, irradiating light through the cathode surface to generate electrons, and allowing the electrons collected on the cathode surface to react with the metal ions to deposit the metal on the cathode surface. According to the method, a highly conductive microcrystalline metal electrode is electrochemically deposited on the surface of the cathode of the solar cell. In the method, light is generally supplied through the surface of the cathode, through which the light can transmit, in contact with the electrolyte solution. Alternatively, in the case of a solar cell in which a cathode and an anode are arranged on the same plane, light may be irradiated through a surface exposed to an air layer that is not in contact with an electrolyte solution. In a general solar cell structure in which a cathode and an anode are arranged opposite to each other, light may be irradiated onto the solar cell to create electrons and deposit a conductive metal electrode on the cathode surface. At this time, a minute amount of direct current is allowed to flow from the outside to prevent damage to the anode surface.

Further, U.S. Pat. No. 4,626,322 suggests a method for photoelectrochemically depositing a metal or transparent conducting oxide material on a semiconductor substrate. The method includes irradiating light onto a semiconductor substrate to generate electrons, and reacting the electrons collected on the surface with metal ions or ions of a metal oxide material present in an electrolyte solution. This method takes advantage of the properties of the semiconductor material capable of generating electrons upon receipt of light to deposit a metal or transparent conducting oxide on the surface of the semiconductor material.

The conventional techniques are associated with methods for electrically depositing a metal or metal oxide on a semiconductor substrate by irradiating light onto the semiconductor substrate whose physical properties and kinds are different from the metal or metal oxide. The conventional techniques fail to suggest solutions to the problems of CIS-based solar cells that the diffusion rates or reaction rates of copper, indium, gallium and selenium or copper, zinc, tin and selenium cations, etc. must be improved or controlled to improve the deposition rates of CIS, CIGS and CZTS thin films and control the compositions thereof.

### SUMMARY OF THE INVENTION

Therefore, the present invention has been made in an effort to solve the problems of the prior art, and it is a first object of the present invention to provide a method for producing a CIS-based thin film based on self-accelerated photoelectrochemical deposition by which the rate of an electrochemical reaction can be accelerated, which shortens the time required to produce the thin film, an interface having a minimized amount of molybdenum selenide can be formed in the course of annealing while possessing a dense microstructure and a flat and uniform surface, and the thin film has a copper-deficient composition. It is a second object of the present invention to provide a CIS-based thin film produced by the method. It is a third object of the present invention to provide a thin-film solar cell including the thin film.

In order to achieve the first object of the present invention, there is provided a method for producing a CIS-based thin film, including

1) mixing precursors of elements constituting a CIS-based compound with a solvent to prepare an electrolyte solution,

2) connecting an electrochemical cell including a working electrode, the electrolyte solution and a counter electrode to a voltage or current applying device to construct an electro-deposition circuit,

3) irradiating light onto the working electrode while at the same time applying a cathodic voltage or current to the working electrode to induce self-accelerated photoelectrochemical deposition, thereby electro-depositing a CIS-based thin film, and

4) annealing the electro-deposited CIS-based thin film under a gas atmosphere including sulfur or selenium.

In an embodiment of the present invention, the CIS-based thin film has the following composition:

Cu(A₁₋ₓBₓ)(Se_{1-y}S_{y})₂

wherein A and B are each independently an element selected from the group consisting of In, Ga, Zn, Sn and Al, and 0≦x, y≦1.

In a further embodiment of the present invention, the CIS-based thin film may be a copper indium selenide (CIS) thin film, a copper indium gallium selenide (CIGS) thin film, or a copper zinc tin sulfide (CZTS) thin film.

In another embodiment of the present invention, the light irradiated during electro-deposition in step 3) may have a wavelength shorter than a wavelength corresponding to the band gap of the compound semiconductor produced by electro-deposition.

In another embodiment of the present invention, the electrolyte solution may further include a supporting electrolyte and a complexing agent.

In another embodiment of the present invention, the precursors include chlorides, sulfates, nitrates, acetates or hydroxides of metals selected from the group consisting of Cu, In, Ga, Zn, Sn, Al and alloys thereof, or include SeO₂, H₂SeO₃ or SeCl₄.

In another embodiment of the present invention, the electrolyte solution may include precursors of Cu, In and Se, and the atomic ratio of Cu, In and Se in the electrolyte solution may be 0.8-1.2:1-5:1.8-2.2.

In another embodiment of the present invention, the electrolyte solution may include precursors of Cu, In and Se, and the atomic ratio of Cu, In and Se in the electrolyte solution may be 1:4:2.

In another embodiment of the present invention, the supporting electrolyte may be KCl or LiCl.

In another embodiment of the present invention, the complexing agent may be triethanolamine (N(CH₂CH₃)₃), citric acid (C₆H₈O₇), tartaric acid (C₄H₆O₆), sulfamic acid (NH₂SO₃H), sodium citrate (Na₃C₆H₅O₇), potassium hydrogen phthalate (C₈H₅KO₄), potassium thiocyanate (KSCN) or a mixture thereof.

In another embodiment of the present invention, the solvent may be water, alcohol or a mixture thereof.

In another embodiment of the present invention, the electrolyte solution may have a pH of 1.5 to 3.

In order to achieve the second object of the present invention, there is provided a CIS-based thin film produced by the method.

In order to achieve the third object of the present invention, there is provided a thin-film solar cell including a CIS-based thin film produced by the method as a light-absorbing layer.

According to the method of the present invention, electrons are generated in the CIS-based thin film deposited through an electrochemical reaction upon irradiation with light during electro-deposition. The electrons are allowed to diffuse along the surface of the thin film and react with the CIS precursor metal ions present in the electrolyte solution. The reaction allows additional deposition of the CIS-based thin film to proceed. That is, the CIS-based thin film becomes thicker and absorbs light to generate a larger amount of electrons, enabling faster deposition of the CIS-based metal, i.e. self-accelerated photoelectrochemical deposition of the CIS-based metal. The self-accelerated photoelectrochemical deposition can shorten the production time of the CIS-based thin film and allows the CIS-based thin film to have a dense microstructure and a flat and uniform surface, achieving high efficiency and quality of the CIS-based thin film. In addition, the wavelength and intensity of light can be controlled such that the CIS-based thin film has a copper-deficient composition necessary for the fabrication of a high-efficiency CIS-based solar cell. Furthermore, the efficiency of use of the raw materials can be increased without the use of an expensive vacuum system, enabling the production of the CIS-based thin film in an economical manner. Moreover, the method of the present invention can be applied to the production of all semiconductor thin films that are capable of forming electron-hole pairs upon absorption of light. The present invention provides a CIS-based thin film produced by the method and a thin-film solar cell including the thin film.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram of an electrochemical cell for the production of a CIS-based thin film according to an embodiment of the present invention;

FIGS. 2a to 2c are images showing the cross-section (2a) and surface (2b) of a CIS-based thin film produced by electro-deposition for 7,200 seconds while applying a constant voltage of −0.5 V under irradiation with light of about 65 mW/cm² from a plasma lighting system (PLS) as a light source in accordance with an embodiment of the present invention, and an XRD pattern of the CIS-based thin film (2c);

FIGS. 3a and 3b are images showing the cross-section (3a) and surface (3b) of a CIS compound thin film produced by electro-deposition for 7,200 seconds while applying a constant voltage of −0.5 V in the absence of light in accordance with the prior art; and

FIG. 4 graphically shows a variation in current when light was irradiated in accordance with the present invention and a variation in current when no light was irradiated in accordance with the prior art, as a function of electro-deposition time.

### DETAILED DESCRIPTION OF THE INVENTION

The present invention will now be described in more detail with reference to the accompanying drawings and examples that follow.

The present invention provides a method for producing a CIS-based thin film as a light-absorbing layer of a thin-film solar cell by using electro-deposition. According to the method of the present invention, light is irradiated onto a CIS-based thin film growing by electro-deposition to generate additional electrons in the CIS-based thin film. The light accelerates the deposition rate of a metal on the surface of the thin film. At this time, the intensity and wavelength of the light are controlled to accelerate the rate of an electrochemical reaction, achieving i) shortened production time of the thin film, ii) improved flatness and density of the thin film surface, iii) a copper-deficient composition of the thin film, and iv) economic production of the thin film. When traditional electrochemical deposition or electro-deposition is referred to as “ED”, an electro-deposition process by which an electrochemical reaction is accelerated by irradiation with light and the acceleration effect is enhanced with increasing thickness of a thin film can be defined as “self-accelerated photoelectrochemical deposition” or “self-accelerated photo-assisted electrochemical deposition”, i.e. SAPED.

The method of the present invention is based on self-accelerated photoelectrochemical deposition. Specifically, the method includes 1) mixing precursors of elements constituting a CIS-based compound with a solvent to prepare an electrolyte solution, 2) connecting an electrochemical cell including a working electrode, the electrolyte solution and a counter electrode to a voltage or current applying device to construct an electro-deposition circuit, 3) irradiating light onto the working electrode while at the same time applying a cathodic voltage or current to the working electrode to induce self-accelerated photoelectrochemical deposition, thereby electro-depositing a CIS-based thin film, and 4) annealing the electro-deposited CIS-based thin film under a gas atmosphere including sulfur or selenium.

In the first step 1), an electrolyte solution for use in the subsequent electro-deposition is prepared. The electrolyte solution includes precursors of elements constituting a desired CIS-based compound, a solvent, other counter ion sources, and one or more additives, such as a complexing agent.

The precursors are not limited so long as they are compounds that can be deposited by electro-deposition to form a CIS-based thin film. For example, the precursors may include chlorides, sulfates, nitrates, acetates or hydroxides of metals selected from the group consisting of Cu, In, Ga, Zn, Sn, Al and alloys thereof. Alternatively, the precursors may include nonmetal precursors, such as selenium oxide (SeO₂), selenious acid (H₂SeO₃) or selenium chloride (SeCl₄). In the case where precursors of Cu, In and Se are used, the atomic ratio of Cu, In and Se in the electrolyte solution is in the range of 0.8-1.2:1-5:1.8-2.2, preferably 1:4:2. The use of the composition of the precursors in the range defined above enables the production of a thin film with good light absorption efficiency, high flatness and high density.

Any solvent that can dissolve the precursors and has an electrical conductivity suitable for implementing the subsequent electro-deposition may be used without limitation in the method of the present invention. The solvent may be, for example, water, alcohol or a mixture thereof.

It is preferred that the pH of the electrolyte solution prepared by mixing the precursors with the solvent is maintained in the range of 1.5 to 3. If the electrolyte solution has a pH lower than 1.5 or higher than 3, it may be difficult to produce a uniform thin film and a plate-like secondary phase such as CuSe may be deposited.

The electrolyte solution may optionally further include one or more additives, such as a supporting electrolyte and a complexing agent, in addition to the precursors and the solvent. The supporting electrolyte serves to increase the electrical conductivity of the electrolyte solution. As the supporting electrolyte, there may be used, for example, potassium chloride (KCl) or lithium chloride (LiCl). The complexing agent serves to regulate the mobility of particular ions in the electrolyte solution. Examples of complexing agents suitable for use in the electrolyte solution include, but are not limited to, triethanolamine (N(CH₂CH₃)₃), citric acid (C₆H₈O₇), tartaric acid (C₄H₆O₆), sulfamic acid (NH₂SO₃H), sodium citrate (Na₃C₆H₅O₇), potassium hydrogen phthalate (C₈H₅KO₄), and potassium thiocyanate (KSCN). These complexing agents may be used alone or as a mixture thereof.

In the subsequent step 2), an electrochemical cell including a working electrode, the electrolyte solution and a counter electrode is connected to a voltage or current applying device to construct an electro-deposition circuit.

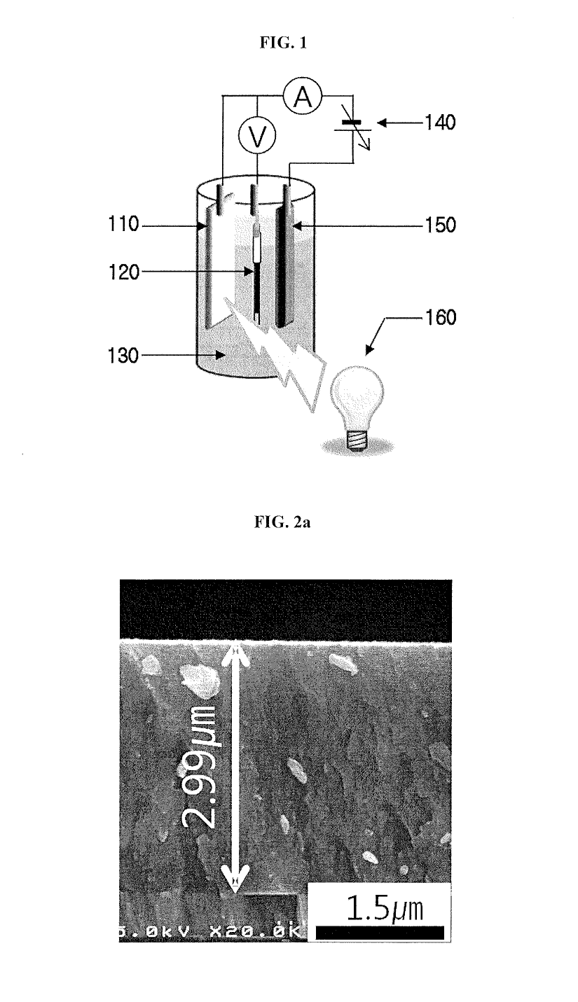

FIG. 1 is a schematic diagram of an electrochemical cell for the production of a CIS-based thin film according to an embodiment of the present invention. Referring to FIG. 1, the electrochemical cell includes a working electrode 110, a reference electrode 120, an electrolyte 130, a voltage or current supply device 140, a counter electrode 150, and a light source 160. An electro-deposition circuit is constructed by filling a solution of the electrolyte 130 in an electrolyte bath, and immersing a substrate, the working electrode 110, the counter electrode 150, the reference electrode 120, etc, in the electrolyte solution. The electro-deposition circuit further includes the light source 160 for light irradiation, i.e. an illumination lamp. The electrolyte bath is preferably made of a transparent material, such as quartz or glass, through which light can easily transmit. The substrate, where a CIS-based compound is electro-deposited to form a light-absorbing layer, is preferably one including molybdenum. The substrate including molybdenum is highly electrically conductive and is relatively cheap. The substrate including molybdenum has a coefficient of thermal expansion similar to that of the constituent CIS-based compound of a light-absorbing layer and has a proper ohmic contact. However, the substrate is not limited to a particular material. For example, the substrate may be made of metals including Ti, stainless steel or transparent conducting oxides such as ITO (Sn-doped In₂O₃), FTO (F-doped SnO₂), AZO (Al-doped ZnO), and GZO (Ga-doped ZnO). The counter electrode 150 and the reference electrode 120 may be made of materials that are generally used in electro-deposition processes. No particular limitation is imposed on the sizes and shapes of the counter electrode 150 and the reference electrode 120. For example, the counter electrode 150 may be made of platinum (Pt). In the case where the substrate, where a CIS-based compound is electro-deposited, is made of molybdenum and the counter electrode 150 is made of platinum, the electro-deposition circuit has the following construction:

(−) Mo|CIS|Electrolyte|Pt (+)

When a compound thin film grows by electro-deposition, i) a flow of electrons or holes in the Mo substrate and the compound thin film (CIS), ii) a reduction reaction of cations at the CIS/electrolyte interface, iii) diffusion of ions in the electrolyte, and iv) an oxidation reaction of anions in the counter electrode (Pt) take place sequentially in the electro-deposition circuit to form one closed circuit. The thickness t of the compound thin film formed by electro-deposition is proportional to the amount of charges flowing in the electro-deposition circuit, as expressed in Equation 1:

$$t = \frac{\int I \cdot d {t}_{ED}}{n F} \cdot \frac{M}{A ρ} ↵ \qquad ( 1 )$$

where I, t_{ED}, n, F, M, A and ρ represent the current flowing in the electro-deposition circuit, the time required for electro-deposition, the number of electrons transferred while depositing one molecule of the compound (n=13 for CIS), the Faraday constant, the molecular weight of the compound, the area of the thin film, and the theoretical density of the thin film, respectively.

The amount of current flowing at a given voltage is proportional to the reaction rates of the steps i) to iv). In the case where one of the reactions is relatively slow, the overall reaction rate is determined by the slowest reaction step. In the present invention, light is used as a catalyst for electrodeposition and is irradiated to accelerate the rate of the slowest reaction of the steps i) to iv), eventually resulting in an increase in the overall reaction rate. Accordingly, the illumination lamp for light irradiation is an essential element of the electro-deposition circuit to achieve the desired effects of the present invention. So long as the entire area of the substrate can be irradiated by the illumination lamp and light from the illumination lamp has a wavelength shorter than a wavelength corresponding to the band gap of a compound semiconductor produced by electro-deposition, the size, form, kind, etc. of the illumination lamp are not particularly limited.

In the next step 3), light is irradiated onto the working electrode, and at the same time, a cathodic voltage or current is applied to electro-deposit a CIS-based thin film.

The electro-deposition of the CIS-based thin film by current application and light irradiation may be carried out, for example, at room temperature and ambient pressure, i.e. at a temperature of 10 to 25° C. and a pressure of 0.9 to 1.1 atm. The voltage (e.g., DC voltage) for current application may be in the range of −0.4 to −0.6 V, preferably −0.5 V, but is not limited to this range. The voltage may be applied for 10 to 120 minutes.

As described above, a light source, from which light is irradiated during electro-deposition in step 3), is required to have a wavelength shorter than a wavelength corresponding to the band gap of the compound semiconductor produced by electro-deposition. For example, when it is intended to electro-deposit CuInSe₂ having a band gap of 1.04 eV, a light source having a wavelength shorter than 1,190 nm is used. The semiconductor absorbs light from a light source capable of meeting the wavelength requirement to create electron-hole pairs.

In the final step 4), the electro-deposited CIS-based thin film is annealed under a gas atmosphere including sulfur or selenium.

The annealing step is carried out to densify the microstructure of the electro-deposited CIS-based thin film through recrystallization or grain growth. The annealing temperature is preferably from 300° C. to 700° C., more preferably from 500° C. to 550° C. If the annealing temperature is lower than 300° C., sufficient grain growth does not occur. Meanwhile, if the annealing temperature is higher than 700° C., glass as a material for the substrate is undesirably liable to warp.

On the other hand, the annealing may be conducted under a selenium atmosphere to prevent the selenium (Se) component from being evaporated from the electro-deposited CIS-based thin film. Alternatively, the annealing may be conducted under an atmosphere where some or all of the selenium atoms are replaced with sulfur (S) atoms. This sulfur atmosphere increases the band gap of the CIS light-absorbing layer having a band gap of 1.04 eV, leading to an increase in Voc ensuring high efficiency. During the annealing, the selenium or sulfur gas reacts with molybdenum to form molybdenum selenide (MoSe₂) or molybdenum sulfide (MoS₂). An appropriate thickness of the molybdenum selenide or molybdenum sulfide brings about increased adhesion and suitable ohmic contact. The thickness is preferably in the range of 50 to 150 nm but is not necessarily limited to this range.

The reaction of the selenium or sulfur gas with molybdenum during the annealing may excessively increase the thickness of the molybdenum selenide or molybdenum sulfide. The increased thickness causes an increase in series resistance, eventually resulting in low efficiency of a solar cell. This problem can be overcome by adjusting the vapor pressure of the selenium or sulfur to an appropriate level. The vapor pressure may be adjusted in various ways depending on the form of the selenium or sulfur. When the selenium or sulfur is used in the form of a solid or powder, the vapor pressure can be adjusted by controlling the temperature of the selenium or sulfur while maintaining the CIS-based thin film at a preset temperature. Meanwhile, when the selenium or sulfur is used in the form of a gas, for example, hydrogen selenide (H₂Se) or hydrogen sulfide (H₂S), the partial pressure of the gas is adjusted to an appropriate level so that the thickness of molybdenum selenide or molybdenum sulfide can be controlled.

The final CIS-based thin film produced by the method of the present invention has the following composition:

Cu(A₁₋ₓBₓ)(Se_{1-y}S_{y})₂

wherein A and B are each independently an element selected from the group consisting of In, Ga, Zn, Sn and Al, and 0≦x, y≦1.

As the CIS-based thin film, there may be specifically exemplified a copper indium selenide (CIS) thin film, a copper indium gallium selenide (CIGS) thin film, or a copper zinc tin sulfide (CZTS) thin film.

The present invention also provides a CIS-based thin film produced by the method based on self-accelerated photoelectrochemical deposition. The CIS-based thin film of the present invention can be used as a high-efficiency, high-quality light-absorbing thin film due to its dense microstructure and flat and uniform surface. Particularly, the CIS-based thin film of the present invention has a copper-deficient composition essential for the fabrication of a high-efficiency CIS-based solar cell.

The present invention also provides a thin-film solar cell including the high-quality thin film as a light-absorbing layer.

The present invention will be explained in more detail with reference to the following examples. However, these examples are given to assist in a further understanding of the invention and are in no way intended to limit the scope of the invention.

### EXAMPLES

### Example 1

A molybdenum electrode was deposited to a thickness of 500 nm on soda-lime glass using a DC sputter to produce a working electrode. A platinum (Pt) sheet was used as a counter electrode and a silver-silver chloride (Ag/AgCl) electrode was used as a reference electrode.

0.24 M potassium chloride, 2.4 mM of copper chloride dihydrate, 9.6 mM indium chloride and 4.8 mM selenium dioxide were mixed in water, and 12 mM sulfamic acid and 12 mM potassium hydrogen phthalate were added thereto to prepare 60 ml of an electrolyte solution. Then, the pH of the electrolyte solution was adjusted to 2.2.

A WPG100 Potentiostat/Galvanostat (WonATech) was used as a potentiostat. Light of about 65 mW/cm² from a plasma lighting system (PLS) was irradiated onto the molybdenum-deposited soda-lime glass substrate as the working electrode and a voltage of −0.5 V was applied by chronoamperometry for 7,200 sec to form a CIS-based thin film. The substrate on which the CIS-based thin film was deposited was washed with distilled water and dried at room temperature and ambient pressure.

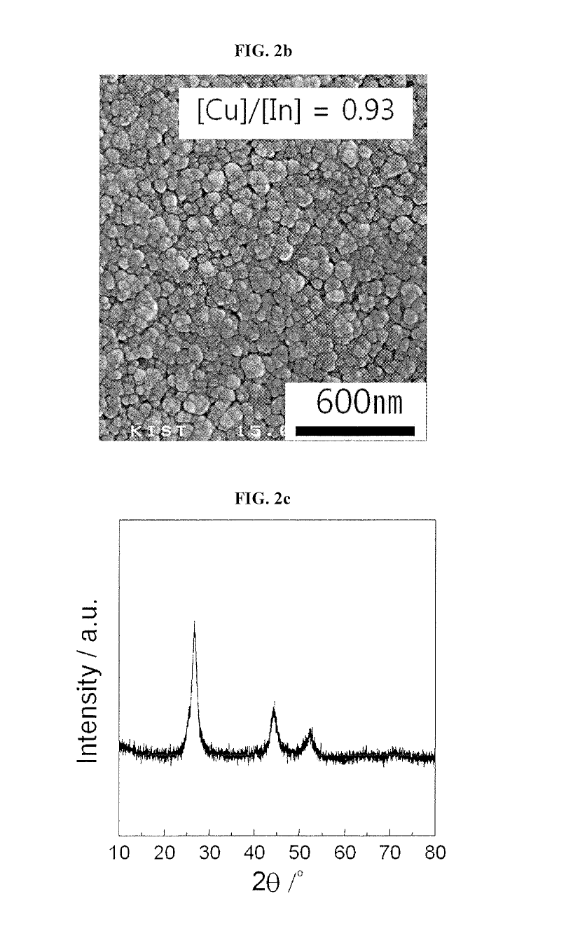

The thickness and density of the CIS-based thin film were determined by observation under a scanning electron microscope (FE-SEM) (S-4200, Hitachi), and the results are shown in FIGS. 2a and 2b, respectively. As shown in FIGS. 2a and 2b, the CIS-based thin film had a uniform thickness of 2.99 μm and also had a very uniform density compared to a thin film produced in Comparative Example 1 that follows. The composition of the CIS-based thin film was analyzed by energy dispersive x-ray spectroscopy (EDS) (S-4200, Hitachi). Referring to FIG. 2b, the ratio of [Cu]/[In] in the CIS-based thin film was 0.93, demonstrating that the thin film had a copper-deficient composition essential for the fabrication of a high-efficiency CIS-based solar cell. In addition, the crystal structure of the CIS-based thin film was analyzed by x-ray diffraction (Xpert Pro MRD) and the results are shown in FIG. 2c. Referring to FIG. 2c, the CIS-based thin film had an α-CuInSe₂ structure in crystalline phase. No trace of any secondary phase was found on the XRD pattern.

### Comparative Example 1

An electrolyte solution was prepared in the same manner as in Example 1. A thin film was formed using the electrolyte solution by electro-deposition in the same manner as in Example 1, except that light was not irradiated.

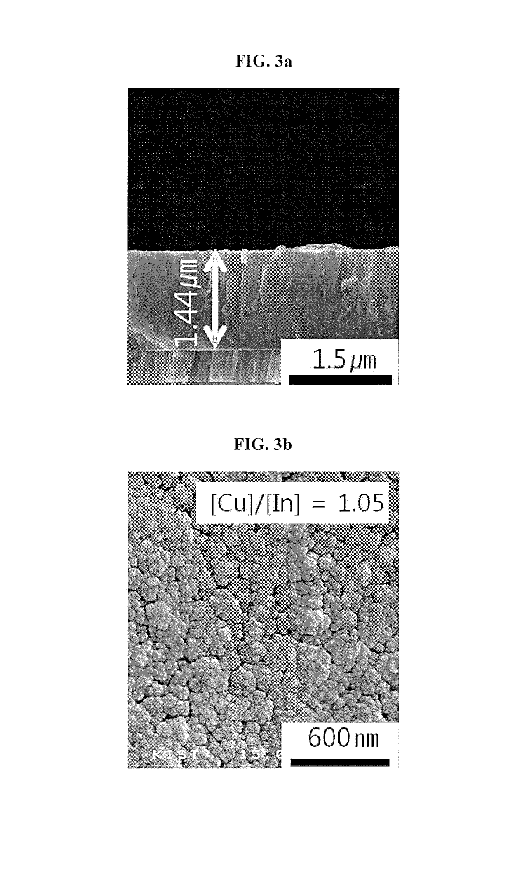

The thickness and density of the CIS-based thin film were determined in the same manner as in Example 1, and the results are shown in FIGS. 3a and 3b, respectively. Referring to FIGS. 3a and 3b, the CIS-based thin film had a thickness of 1.44 μm, which was thinner than the thickness (2.99 μm) of the thin film produced in Example 1. The thicker thin film of Example 1 can be explained by the fact that the electrochemical reaction is accelerated by light irradiation.

Referring to FIG. 3b, many valleys were on the surface of the thin film, unlike the surface of the thin film of Example 1 shown in FIG. 2b. From these observations, it can be confirmed that the thin film of Example 1 had a much higher density and a very flat, uniform surface. In addition, the composition of the CIS-based thin film of Comparative Example 1 was observed in the same manner as in Example 1. Referring to FIG. 3b, the ratio of [Cu]/[In] in the CIS-based thin film of Comparative Example 1 was 1.05, demonstrating that the thin film had a copper-excess composition. From these results, it can be seen that the method of the present invention accelerates the electro-deposition reaction of indium (In) to produce a thin film having a copper-deficient composition essential for the fabrication of a high-efficiency CIS-based solar cell.

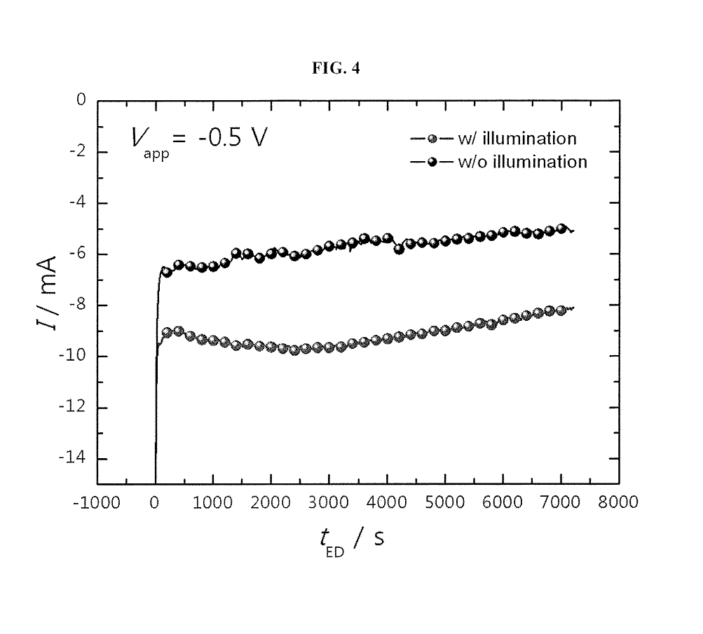

FIG. 4 shows a variation in electro-deposition current when light was irradiated in accordance with the present invention and a variation in electro-deposition current when no light was irradiated in accordance with the prior art, as a function of electro-deposition time. Referring to FIG. 4, the illumination increased the amount of current, which indicates that the electrochemical reaction rate can be regulated and the time required for electro-deposition can be shortened by controlling the light intensity. As the thickness of the CIS-based thin film of Example 1 was increased with the passage of time at the initial stage of electro-deposition under illumination, the amount of electrons generated was increased, resulting in an increase in the amount of current. The increased amount of current made the CIS-based thin film thicker. The thicker CIS-based thin film absorbed light to generate a larger amount of current. This deposition process was accelerated with time, that is, self-accelerated photoelectrochemical deposition proceeded. At the latter stage of electro-deposition, the electrical resistance of the CIS-based thin film was increased considerably with increasing thickness thereof, leading to a gradual reduction in electro-deposition current.

Explanation of reference numerals

| | |
|---|---|
| 110: Working electrode | 120: Reference electrode |
| 130: Electrolyte | 140: Voltage or current supply device |
| 150: Counter electrode | 160: Light source |

What is claimed is:

1. A method for producing a CIS-based thin film, comprising
1) mixing precursors of elements constituting a CIS-based compound with a solvent to prepare an electrolyte solution,
2) connecting an electrochemical cell comprising a working electrode, the electrolyte solution and a counter electrode to a voltage or current applying device to construct an electro-deposition circuit,
3) irradiating light onto the working electrode while at the same time applying a cathodic voltage or current to the working electrode to induce self-accelerated photoelectrochemical deposition, thereby electro-depositing a CIS-based thin film, and
4) annealing the electro-deposited CIS-based thin film under a gas atmosphere comprising sulfur or selenium.

2. The method according to claim 1, wherein the CIS-based thin film has the following composition:
Cu(A₁₋ₓBₓ)(Se_{1-y}S_{y})₂
wherein A and B are each independently an element selected from the group consisting of In, Ga, Zn, Sn and Al, and 0≦x, y≦1.

3. The method according to claim 1, wherein the CIS-based thin film is a copper indium selenide (CIS) thin film, a copper indium gallium selenide (CIGS) thin film, or a copper zinc tin sulfide (CZTS) thin film.

4. The method according to claim 1, wherein the light irradiated during electro-deposition in step 3) has a wavelength shorter than a wavelength corresponding to the band gap of the compound semiconductor produced by electro-deposition.

5. The method according to claim 1, wherein the electrolyte solution further comprises a supporting electrolyte and a complexing agent.

6. The method according to claim 1, wherein the precursors comprise chlorides, sulfates, nitrates, acetates or hydroxides of metals selected from the group consisting of In, Ga, Zn, Sn, Al and alloys thereof, or comprise SeO₂, H₂SeO₃ or SeCl₄.

7. The method according to claim 1, wherein the electrolyte solution comprises precursors of Cu, In and Se, and the atomic ratio of Cu, In and Se in the electrolyte solution is 0.8-1.2:1-5:1.8-2.2.

8. The method according to claim 1, wherein the electrolyte solution comprises precursors of Cu, In and Se, and the atomic ratio of Cu, In and Se in the electrolyte solution is 1:4:2.

9. The method according to claim 5, wherein the supporting electrolyte is KCl or LiCl as a counter ion source.

10. The method according to claim 5, wherein the complexing agent is triethanolamine (N(CH₂CH₃)₃), citric acid (C₆H₈O₇), tartaric acid (C₄H₆O₆), sulfamic acid (NH₂SO₃H), sodium citrate (Na₃C₆H₅O₇), potassium hydrogen phthalate (C₈H₅KO₄), potassium thiocyanate (KSCN) or a mixture thereof.

11. The method according to claim 1, wherein the solvent is water, alcohol or a mixture thereof.

12. The method according to claim 1, wherein the electrolyte solution has a pH of 1.5 to 3.

13. A CIS-based thin film produced by the method according to claim 1.

14. A thin-film solar cell comprising the CIS-based thin film according to claim 13 as a light-absorbing layer.
